(19) United States
(12) Patent Application Publication
(10) Pub. No.: US 2015/0114295 A1
(43) Pub. Date: Apr. 30, 2015

(54) DEPOSITION APPARATUS

(71) Applicant: ASM IP Holding B.V., Almere (NL)

(72) Inventors: Young Hoon KIM, Cheonan-si (KR); Dae Youn KIM, Daejeon (KR); Dong Rak JUNG, Cheonan-si (KR); Young Seok CHOI, Daejeon (KR); Sang Wook LEE, Gunpo-si (KR)

(21) Appl. No.: 14/521,588

(22) Filed: Oct. 23, 2014

(30) Foreign Application Priority Data
Oct. 29, 2013 (KR) 10-2013-0129356

(51) Int. Cl. C23C 16/50; C23C 16/455; C23C 16/44; C23C 16/46

(52) U.S. Cl. CPC C23C 16/50; C23C 16/46; C23C 16/45561; C23C 16/4412
USPC 118/723 R

(57) ABSTRACT

An exemplary embodiment of the present invention provides a deposition apparatus including: a substrate support for supporting a substrate; a reaction chamber wall defining a reaction chamber and contacting the substrate support; a plurality of gas inlets connected to the reaction chamber wall; a remote plasma unit connected to at least one of the plurality of gas inlets; and a gas-supplying path connected to the plurality of gas inlets and defining a reaction region along with the substrate support. A plurality of gases passing through the plurality of gas inlets move along the gas-supplying path to be directly supplied onto the substrate without contacting other parts of the reactor.

### CROSS-REFERENCE TO RELATED APPLICATION

This application claims priority to and the benefit of Korean Patent Application No. 10-2013-0129356 filed in the Korean Intellectual Property Office on Oct. 29, 2013, the entire contents of which are incorporated herein by reference.

### BACKGROUND OF THE INVENTION

(a) Field of the Invention

The present invention relates to a deposition apparatus.

(b) Description of the Related Art

In semiconductor deposition processes, a high temperature process at 500° C. or above has been frequently used to deposit chemical materials supplied to a reaction space in which a substrate is placed.

However, as a size a semiconductor device gradually become smaller, there is a growing demand for a low temperature process to prevent deterioration of characteristics due to thermal shock.

In such a low temperature process, a plasma process, in which plasma is used to activate a process gas, is introduced.

When the plasma is used to activate the process gas, chemical materials deposited on the substrate can be activated while a heater temperature is maintained at a low temperature.

Accordingly, deterioration of characteristics of the device due to the thermal shock may be prevented and thus, deformation of a process equipment due to high temperatures may be prevented, thereby allowing easier equipment maintenance.

The plasma processes are generally classified into an in-situ plasma method in which the plasma is directly generated on the substrate positioned on the reaction space, and a remote plasma method in which the plasma is generated outside of a reactor to supply active species to the reaction space.

When using the in-situ plasma method, there are problems of deteriorated characteristics of sub layer materials, such as substrate damage due to accelerated electrons, oxidization of the sub layer materials due to activated oxygen radicals, etc. because the plasma is generated on the substrate.

In order to solve the problems of the in-situ plasma method, the remote plasma method is used.

However, when using the remote plasma method, the active species may become extinct while being supplied to the reactor.

Particularly, when supply passages of the active species are complicated, such extinction of the active species may result from collision of the active species against inner walls of an active species supply conduit, chamber walls, or surfaces of a gas spraying means such as a showerhead.

Accordingly, as the passages inside the reactor are complicated, the active species generated by the remote plasma may become extinct to deteriorate efficiency of the remote plasma process.

The above information disclosed in this Background section is only for enhancement of understanding of the background of the invention and therefore it may contain information that does not form the prior art that is already known to a person of ordinary skill in the art.

### SUMMARY OF THE INVENTION

The present invention has been made in an effort to provide a deposition apparatus for preventing efficiency deterioration of a remote plasma process.

An exemplary embodiment of the present invention provides a deposition apparatus including: a substrate support for supporting a substrate; a reaction chamber wall defining a reaction chamber and contacting the substrate support; a plurality of gas inlets connected to the reaction chamber wall; a remote plasma unit connected to at least one of the plurality of gas inlets; and a gas-supplying path connected to the plurality of gas inlets and defining a reaction region along with the substrate support. A plurality of gases passing through the plurality of gas inlets move along the gas-supplying path to be directly supplied onto the substrate without contacting other parts of the reactor.

The gas-supplying path may internally have a fallopian tube form in which its upper portion is connected to the plurality of gas inlets and its radius increases getting closer to the lower portion.

At least one of the plurality of gases passing through the plurality of gas inlets may be activated in the remote plasma unit, move along the gas-supplying path, and be directly supplied onto the substrate without contacting other parts of the reactor.

The deposition apparatus may further include a gas exhaust path for exhausting gas of the reaction chamber, and a gas exhaust hole connected to the gas exhaust path.

The gas exhaust path may be formed between the reactor wall and the gas-supplying path to completely enclose the gas-supplying path, and the gas exhaust hole may be positioned above the deposition apparatus.

The deposition apparatus may further include a heater attached to the substrate support.

The deposition apparatus may further include a heating plate attached to the reactor wall.

According to the deposition apparatus in accordance with the exemplary embodiment of the present invention, the efficiency deterioration of the remote plasma process can be prevented.

### BRIEF DESCRIPTION OF THE DRAWINGS

FIG. 1 is a cross-sectional view of a deposition apparatus according to an exemplary embodiment of the present invention.

FIG. 2 is a drawing illustrating a portion of the deposition apparatus according to the exemplary embodiment of the present invention.

### DETAILED DESCRIPTION OF THE EMBODIMENTS

The present invention will be described more fully hereinafter with reference to the accompanying drawings, in which exemplary embodiments of the invention are shown.

As those skilled in the art would realize, the described embodiments may be modified in various different ways, all without departing from the spirit or scope of the present invention.

In the drawings, the thickness of layers, films, panels, regions, etc. are exaggerated for clarity.

Like reference numerals designate like elements throughout the specification.

It will be understood that when an element such as a layer, film, region, or substrate is referred to as being “on” another element, it can be directly on the other element or intervening elements may also be present.

In contrast, when an element is referred to as being “directly on” another element, there are no intervening elements present.

A deposition apparatus according to an exemplary embodiment of the present invention will now be described with reference to the drawings.

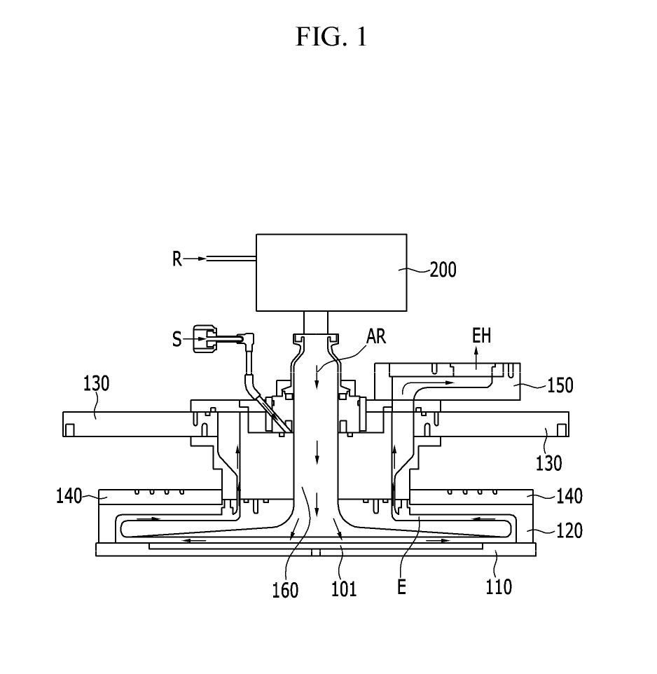

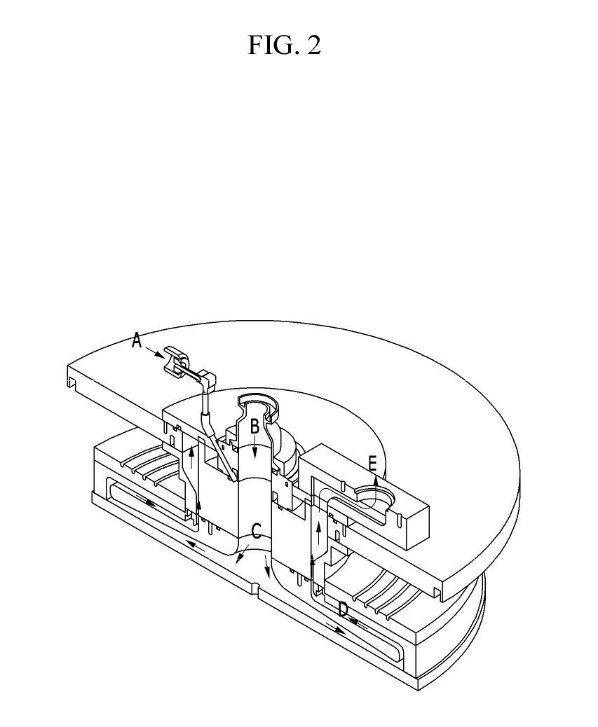

Referring to FIGS. 1 and 2, the deposition apparatus according to the exemplary embodiment of the present invention will now be described.

FIG. 1 is a cross-sectional view of the deposition apparatus according to the exemplary embodiment of the present invention, and FIG. 2 is a drawing illustrating a portion of the deposition apparatus according to the exemplary embodiment of the present invention.

First, Referring to FIG. 1, the deposition apparatus includes a reactor 100 and a remote plasma unit 200 that is coupled to the reactor 100 to supply active species.

The reactor 100 will be described.

The deposition apparatus according to the exemplary embodiment of the present invention includes a substrate support 110 and a reactor wall 120 contacting each other to define a reaction space, and a reactor cover 130.

A substrate 101 to which a thin film is to be deposited is placed on the substrate support 110.

Though not illustrated in the drawings, the deposition apparatus may further include a heater, which is attached to the substrate support 110 to heat it.

The heater attached to the substrate support 110 serves to increase the substrate temperature to a temperature required for a process.

A heating plate 140 is attached to the reactor wall 120, and the heating plate 140, along with the heater mounted on the substrate support 110, heats an upper portion of the reactor to maintain uniform temperature distribution of a reaction space, thereby allowing a thin film deposition process to be smoothly performed and preventing condensation of a source gas and contaminants caused thereby due to temperature non-uniformity inside the reaction space.

In the exemplary embodiment of the present invention, the heating plate 140 is installed above the reactor wall 120, but may be additionally installed at lateral sides thereof and at other portions of the reactor wall.

A first gas inlet S and a gas outlet EH are formed at the reactor cover 130, and an exhaust unit such as an exhaust pump 150 is coupled to the gas exhaust hole EH.

The gas exhaust hole EH is connected to a gas exhaust path E.

The first gas inlet S is connected to a gas-supplying path 160 positioned at a center portion of the reactor, and supplies gas to the reaction space.

A second gas inlet R is connected to the remote plasma unit 200.

The gas-supplying path 160 is formed inside the reactor wall 120 and the reactor cover 130 so as to allow the supplied gas to be introduced onto the substrate 101.

The gas-supplying path 160 defines a reaction region along with the substrate support 110.

According to the exemplary embodiment of the present invention, the source gas supplied through the first gas inlet S and the reaction gas supplied through the second gas inlet R share the gas-supplying path 160.

According to the exemplary embodiment of the present invention, the deposition apparatus includes the gas-supplying path 160, of which an inner diameter thereof gradually increases.

In more detail, the gas-supplying path 160 has a relatively small first diameter at an upper end portion through which the reaction gas is supplied and a second diameter at a lower end portion that is wider than the substrate 101 facing the gas-supplying path 160, and may have various types of structures including a fallopian tube form, an upper portion of which is connected to the plurality of gas inlets and a radius of which rapidly increases coming closer to a lower end portion adjacent to the substrate 101, a cone form, or a structure in which the lower end portion expands.

There is no additional gas spraying means inside the gas-supplying path 160 or at the end portion thereof.

Thus, the lower end portion of the gas-supplying path 160 directly faces the substrate 101.

Now, in the deposition apparatus according to the exemplary embodiment of the present invention, how the gases are supplied and exhausted will be described in detail with reference to FIG. 2 along with FIG. 1.

In FIGS. 1 and 2, arrows schematically illustrate flows of gases.

The source gas is supplied through the first gas inlet S, as shown in “A” of FIG. 2, and the reaction gas is supplied through the remote plasma unit 200, as shown in “B” of FIG. 2, such that they are activated by plasma so as to supply an activated reactant marked as AR.

However, on the contrary, the reaction gas may be supplied through the first gas inlet S and the source gas may be supplied through the second gas inlet R.

As shown in “C” of FIG. 2, the supplied source and reaction gases are supplied directly onto the substrate 101 without passing through an additional gas spraying means.

The source and reaction gases react with each other while passing over the substrate 101, and the residual gas and the like move along the gas exhaust path E, as shown in “D” of FIG. 2, and are then discharged to the outside through the gas exhaust hole EH, as shown in “E” of FIG. 2.

The gas exhaust path E is formed between the reactor wall 120 and the gas-supplying path 160, and has a shape to completely enclose the gas-supplying path 160.

The gas exhaust path E is connected to the gas exhaust hole EH above the deposition apparatus. In addition, according to the deposition apparatus in accordance with the exemplary embodiment of the present invention, each gas is supplied to a center portion of the reactor along the gas-supplying path 160 and radially reaches over the substrate to deposit the thin film thereto, uniformity of the thin film can be further improved, unlike as shown in the conventional exemplary embodiment (Korean Patent No. 624030) in which gases flow laterally only in one direction.

In addition, since the discharged gas is exhausted over the reactor and the gas exhaust path E has a structure for completely enclosing the gas-supplying path 160, the reactor having a simpler configuration, higher efficiency, and easier maintenance can be constructed compared with the conventional exemplary embodiment (Korean Patent No. 624030).

As described above, according to the deposition apparatus in accordance with the exemplary embodiment of the present invention, the gas-supplying path does not internally have an additional gas spraying means such as a showerhead.

That is, because there is no additional gas spraying means installed at the end portion of the gas-supplying path, the lower end portion of the gas-supplying path directly faces the substrate 101.

Thus, while the active species activated by the plasma in the remote plasma unit 200 is being supplied onto the substrate 101, they can be prevented from becoming extinct due to the gas spraying means. As a result, the efficiency deterioration of the remote plasma process can be prevented.

In addition, since each gas is supplied through the gas-supplying path 160 that is formed at the center portion of the reactor, the uniformity of the thin film can be improved, a reactor having a simpler configuration, higher efficiency, and easier maintenance can be constructed, because the gas exhaust path has the structure for enclosing the gas-supplying path 160.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a substrate support for supporting a substrate;
a reaction chamber wall defining a reaction chamber and contacting the substrate support;
a plurality of gas inlets connected to the reaction chamber wall;
a remote plasma unit connected to at least one of the plurality of gas inlets; and
a gas-supplying path connected to the plurality of gas inlets and defining a reaction region along with the substrate support,
wherein a plurality of gases passing through the plurality of gas inlets move along the gas-supplying path to be directly supplied to the substrate without contacting other parts of the reactor.

2. The deposition apparatus of claim 1, wherein
the gas-supplying path internally has a fallopian tube form in which its upper portion is connected to the plurality of gas inlets and its radius increases getting closer to its lower portion.

3. The deposition apparatus of claim 2, wherein
at least one of the plurality of gases passing through the plurality of gas inlets is activated in the remote plasma unit, moves along the gas-supplying path, and is directly supplied onto the substrate without contacting the other parts of the reactor.

4. The deposition apparatus of claim 3, further comprising:
a gas exhaust path for exhausting the gas of the reaction chamber; and
a gas exhaust hole connected to the gas exhaust path.

5. The deposition apparatus of claim 4, wherein
the gas exhaust path is formed between the reactor wall and the gas-supplying path to completely enclose the gas-supplying path, and the gas exhaust hole is positioned above the deposition apparatus.

6. The deposition apparatus of claim 5, further comprising
a heater attached to the substrate support.

7. The deposition apparatus of claim 6, further comprising
a heating plate attached to the reactor wall.

8. The deposition apparatus of claim 1, wherein p1 at least one of the plurality of gases passing through the plurality of gas inlets is activated in the remote plasma unit, moves along the gas-supplying path, and is directly supplied onto the substrate without contacting the other parts of the reactor.

9. The deposition apparatus of claim 8, further comprising:
a gas exhaust path for exhausting the gas of the reaction chamber; and
a gas exhaust hole connected to the gas exhaust path.

10. The deposition apparatus of claim 9, wherein
the gas exhaust path is formed between the reactor wall and the gas-supplying path to completely enclose the gas-supplying path, and the gas exhaust hole is positioned above the deposition apparatus.

11. The deposition apparatus of claim 10, further comprising
a heater attached to the substrate support.

12. The deposition apparatus of claim 11, further comprising
a heating plate attached to the reactor wall.
